(19) United States
(12) Patent Application Publication
(10) Pub. No.: US 2025/0359322 A1
(43) Pub. Date: Nov. 20, 2025

(54) DIELECTRIC INNER SPACERS FOR NANOSHEET TRANSISTORS

(71) Applicant: International Business Machines Corporation, Armonk, NY (US)

(72) Inventors: Shay Reboh, Guilderland, NY (US); Junli Wang, Slingerlands, NY (US); Jay William Strane, Wappingers Falls, NY (US); Shogo Mochizuki, Mechanicville, NY (US)

(21) Appl. No.: 18/668,475

(22) Filed: May 20, 2024

(51) Int. Cl. H01L 27/092; H01L 21/822; H01L 29/06; H01L 29/423; H01L 29/66; H01L 29/775

(52) U.S. Cl. CPC H10D 84/856; H10D 30/014; H10D 30/43; H10D 30/6735; H10D 62/121; H10D 64/017; H10D 64/018; H10D 84/038; H10D 88/01; H10D 30/6736

(57) ABSTRACT

A semiconductor device comprises a first nanosheet transistor structure, a second nanosheet transistor structure stacked on the first nanosheet transistor structure, and a semiconductor layer disposed between the first nanosheet transistor structure and the second nanosheet transistor structure. A first dielectric spacer is disposed around a first end portion of the semiconductor layer, and a second dielectric spacer disposed around a second end portion of the semiconductor layer. The second end portion of the semiconductor layer is disposed opposite the first end portion.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming dielectric spacers for nanosheet transistors.

In one embodiment, a semiconductor device comprises a first nanosheet transistor structure, a second nanosheet transistor structure stacked on the first nanosheet transistor structure, and a semiconductor layer disposed between the first nanosheet transistor structure and the second nanosheet transistor structure. A first dielectric spacer is disposed around a first end portion of the semiconductor layer, and a second dielectric spacer disposed around a second end portion of the semiconductor layer. The second end portion of the semiconductor layer is disposed opposite the first end portion.

In another embodiment, a semiconductor device comprises a plurality of gate structures alternately stacked with a plurality of channel layers, wherein the plurality of channel layers contact at least one source/drain region disposed on at least one side of the plurality of gate structures and the plurality of channel layers. A semiconductor layer is disposed between a first gate structure and a second gate structure of the plurality of gate structures. At least one dielectric spacer is disposed around at least one end portion of the semiconductor layer, wherein the semiconductor layer is electrically isolated from the at least one source/drain region.

In another embodiment, a semiconductor device comprises a plurality of gate structures stacked with a plurality of channel layers, wherein the plurality of channel layers contact at least one source/drain region disposed on at least one side of the plurality of gate structures and the plurality of channel layers. Two or more gate structures of the plurality of gate structures are disposed between two adjacent channel layers of the plurality of channel layers, and a dielectric spacer is disposed on sides of each of the two or more gate structures. The dielectric spacer comprises a continuous structure from a first one of the two or more gate structures to a last one of the two or more gate structures. A semiconductor layer is disposed between each pair of adjacent gate structures of the two or more gate structures. The dielectric spacer is disposed on sides of each semiconductor layer and each semiconductor layer is electrically isolated from the at least one source/drain region.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure illustrating semiconductor nanosheet layers and a dummy gate, according to an embodiment of the invention.

FIG. 2A depicts a cross-sectional view of a semiconductor structure following lateral recessing of sacrificial layers, according to an embodiment of the invention.

FIG. 2B depicts a cross-sectional view of an enlarged portion of FIG. 2A, according to an embodiment of the invention.

FIG. 3A depicts a cross-sectional view of a semiconductor structure following inner spacer formation, according to an embodiment of the invention.

FIG. 3B depicts a cross-sectional view of the enlarged portion of FIG. 2A, according to an embodiment of the invention.

FIG. 4A depicts a cross-sectional view of a semiconductor structure following source/drain region formation, inter-layer dielectric (ILD) layer formation, dummy gate and sacrificial semiconductor layer removal, and replacement metal gate (RMG) formation, according to an embodiment of the invention.

FIG. 4B depicts a cross-sectional view of an enlarged portion of FIG. 4A, according to an embodiment of the invention.

FIG. 5A depicts a cross-sectional view of a semiconductor structure illustrating semiconductor nanosheet layers and a dummy gate, according to an embodiment of the invention.

FIG. 5B depicts a cross-sectional view of an enlarged portion of the semiconductor structure of FIG. 5A following inner spacer formation, according to an embodiment of the invention.

FIG. 6A depicts a cross-sectional view of a semiconductor structure illustrating semiconductor nanosheet layers and a dummy gate, according to an embodiment of the invention.

FIG. 6B depicts a cross-sectional view of an enlarged portion of the semiconductor structure of FIG. 6A following inner spacer formation, according to an embodiment of the invention.

FIG. 7 depicts a cross-sectional view of a semiconductor structure following dummy gate and sacrificial semiconductor layer removal, according to an embodiment of the invention.

FIG. 8 depicts a cross-sectional view of a semiconductor structure following dummy gate and sacrificial semiconductor layer removal, and removal of a portion of a thin semiconductor sheet, according to an embodiment of the invention.

### DETAILED DESCRIPTION

Illustrative embodiments of the invention may be described herein in the context of illustrative methods for forming dielectric spacers for nanosheet transistors, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

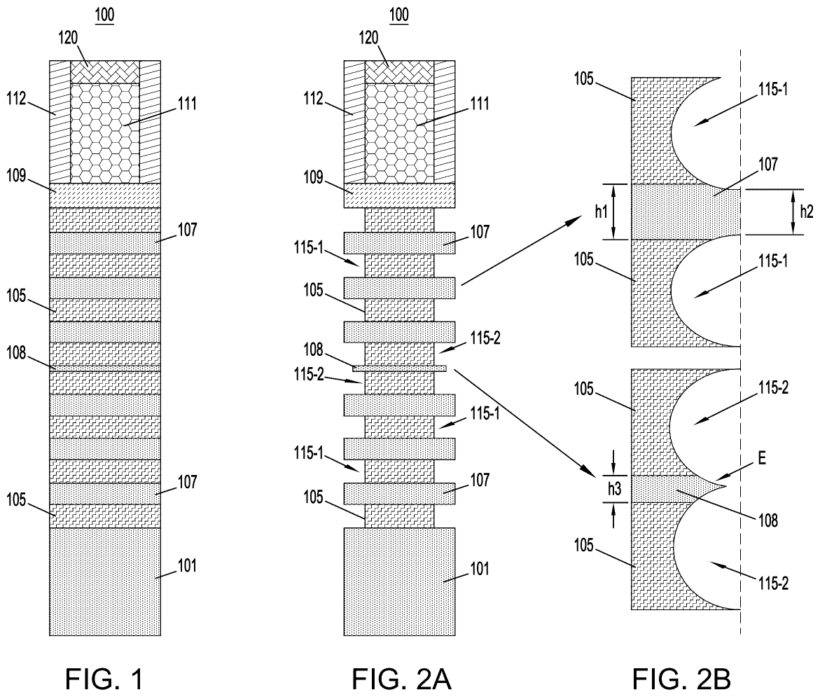

Referring to FIG. 1, a semiconductor structure 100 includes a stacked structure of sacrificial layers 105 and channel layers 107. A semiconductor layer 108, which is thinner (has a smaller vertical height) than the channel layers 107 and the sacrificial layers 105 is disposed between two of the sacrificial layers 105. As described in more detail herein, the semiconductor layer 108 is located in an inter-device region between what will be a first device (e.g., first nanosheet transistor) and a second device (e.g., second nanosheet transistor). In an illustrative embodiment, the sacrificial layers 105 comprise silicon germanium (SiGe) and the channel layers 107 and semiconductor layer 108 comprise silicon. In illustrative embodiments, the sacrificial layers 105 comprise a germanium concentration of about 25% (e.g., SiGe25), but the embodiments are not necessarily limited to SiGe25 for the sacrificial layers 105.

A semiconductor substrate 101 comprises semiconductor material including, but not limited to, silicon (Si), III-V, II-V compound semiconductor materials or other like semiconductor materials. In addition, multiple layers of the semiconductor materials can be used as the semiconductor material of the semiconductor substrate 101.

Except where the semiconductor layer 108 is located, the sacrificial layers 105 and channel layers 107 are epitaxially grown in an alternating and stacked configuration on the semiconductor substrate 101. The semiconductor layer 108 is also epitaxially grown. In the alternating configuration, a first sacrificial layer 105 is followed by a first channel layer 107 on the first sacrificial layer 105, which is followed by a second sacrificial layer 105 on the first channel layer 107, and so on. As can be understood, the sacrificial and channel layers 105 and 107, and the semiconductor layer 108 are epitaxially grown from their corresponding underlying semiconductor layers.

While eight sacrificial layers 105, six channel layers 107 and one semiconductor layer 108 are shown, the embodiments of the present invention are not necessarily limited to the shown number of sacrificial, channel and semiconductor layers 105, 107 and 108, and there may be more or less layers in the same or similar configuration depending on design constraints. The sacrificial layers 105, as described further herein, are eventually removed and replaced by gate structures.

Although SiGe is described as a sacrificial material for sacrificial layers 105, other materials can be used as long as the sacrificial layers 105 have the property of being able to be removed selectively compared to the material of the channel layers 107 and the semiconductor layer 108.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height (e.g., vertical height/thickness) of the sacrificial layers 105 can be in the range of about 6 nm to about 15 nm depending on the application of the device. Also, in a non-limiting illustrative embodiment, a height (e.g., vertical height/thickness) of the channel layers 107 can be in the range of about 6 nm to about 15 nm depending on the desired process and application. In a non-limiting illustrative embodiment, a height (e.g., vertical height/thickness) of the semiconductor layer 108 can be in the range of about 1 nm to about 5 nm, such as from about 2 nm to about 3 nm, depending on the desired process and application. In accordance with an embodiment of the present invention, each of the channel layers 107 has the same or substantially the same composition and size as each other, and each of the sacrificial layers 105 has the same or substantially the same composition and size as each other.

A dielectric layer 109 is disposed on top of the uppermost sacrificial layer 105. The dielectric material of the dielectric layer 109 may comprise, for example, silicon oxide (SiOₓ) (where x is for example, 2, 1.99 or 2.01), silicon oxycarbide (SiOC), silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof. The dielectric layer 109 is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

A dummy gate portion 111 is formed on the dielectric layer 109 and, although not shown, around the stacked nanosheet configuration of the sacrificial layers 105, channel layers 107 and semiconductor layer 108. The dummy gate portion 111 includes, but is not necessarily limited to, an amorphous silicon (a-Si) layer. The dummy gate portion 111 is deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer. A hardmask layer 120 is formed on the dummy gate portion 111. The hardmask layer 120 comprises, for example, a nitride such as SiN, SiON, SiCN, BN, SiBN, SiBCN, SiOCN, combinations thereof or other nitride material.

Gate spacers 112 are formed on sides of the hardmask layer 120 and dummy gate portion 111 by one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOₓ, and combinations thereof. According to an embodiment, the hardmask layer 120 and gate spacers 112 can be the same material or different materials. The gate spacers 112 can be formed by any suitable techniques such as deposition followed by directional etching. Deposition may include but is not limited to, ALD or CVD. Directional etching may include but is not limited to, reactive ion etching (RIE).

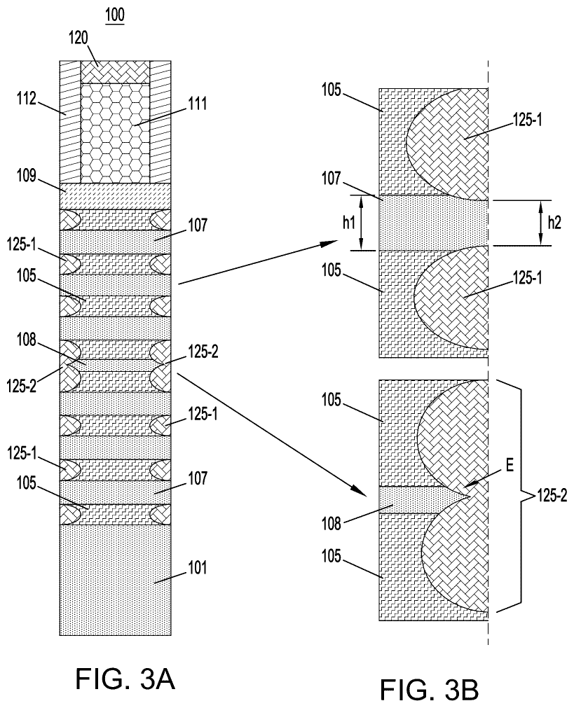

Referring to FIGS. 2A and 2B, due to, for example, germanium in the sacrificial layers 105, lateral etching of the sacrificial layers 105 can be performed selective to the channel layers 107 and to the semiconductor layer 108, such that the side portions of the sacrificial layers 105 can be removed to create first and second vacant areas 115-1 and 115-2 to be filled in by first type inner spacers 125-1 and second type inner spacers 125-2 (see FIGS. 3A and 3B). As can be seen in FIG. 2B, which is an enlarged view of a portion of FIG. 2A, the first and second vacant areas 115-1 and 115-2 have a rounded shape on an internal side of the first and second vacant areas 115-1 and 115-2. Alternatively, the first and second vacant areas 115-1 and 115-2 can have, for example, a square or rectangular shape. As can be seen in FIG. 2B, in the case of the channel layers 107, in forming the first vacant areas 115-1, although lateral etching of the sacrificial layers 105 is selective with respect to the channel layers 107, portions of the channel layers 107 are etched and the height (thickness) of the channel layers 107 is reduced at end portions thereof from an original first height h1 to a second height h2. As can be understood, FIG. 2B illustrates lateral etching on the right side, and similar lateral etching occurs on the left side as shown in FIG. 2A so that the height (thickness) of the channel layers 107 is reduced at left and right end portions thereof.

In the case of the semiconductor layer 108, in forming the second vacant areas 115-2, although lateral etching of the sacrificial layers 105 is selective with respect to the semiconductor layer 108, portions of the semiconductor layer 108 are etched. Due to a smaller original height (thickness) h3 of the semiconductor layer 108 original end portions of the semiconductor layer 108 are removed to create new end portions (E), which are recessed inward from the original end portions. As can be understood, FIG. 2B illustrates lateral etching on the right side, and similar lateral etching occurs on the left side as shown in FIG. 2A so that original end portions of the semiconductor layer 108 are removed to create new end portions (E) and left and right sides thereof.

Referring to FIGS. 3A and 3B, dielectric material is deposited to fill-in the first and second vacant areas 115-1 and 115-2 to create first type inner spacers 125-1 and second type inner spacers 125-2. In illustrative embodiments, the dielectric material is conformally deposited in the first and second vacant areas 115-1 and 115-2 and on and around the stacked structure including the sacrificial layers 105, channel layers 107, dummy gate portion 111, gate spacers 112 and hardmask layer 120. Deposition of the dielectric material can be performed using one or more conformal deposition techniques including, but not necessarily limited to, CVD or ALD. The dielectric material includes, for example, SiOₓ, SiN, SiON, SiCN, BN, SiBN, SiBCN or SiOCN.

Portions of the dielectric material not filling the first and second vacant areas 115-1 and 115-2 are removed using, for example, isotropic etching to form the first type inner spacers 125-1 and second type inner spacers 125-2 covering the sacrificial layers 105 and/or the remaining portion of the semiconductor layer 108. The isotropic etching process can include, but is not necessarily limited, a wet etch process using, for example, diluted high temperature phosphoric acid and hydrofluoric (HF) acid, or a dry etch process, such as isotropic CF₄ or SF₆ to remove excess portions of the deposited dielectric material. The gate spacers 112 can be formed from the same or similar material to that of the first type inner spacers 125-1 and second type inner spacers 125-2.

As can be seen in FIGS. 3A and 3B, the first type inner spacers 125-1 and second type inner spacers 125-2 have a rounded shape on internal sides thereof. Alternatively, the first type inner spacers 125-1 and second type inner spacers 125-2 can have square or rectangular shapes on internal sides thereof. Due to pinching off during the conformal deposition, the second type inner spacers 125-2 on left and right sides respectively form a continuous structure from a top sacrificial layer 105 to a bottom sacrificial layer 105 around an end portion E of the semiconductor layer 108 such that each second type inner spacer 125-2 covers an end portion E at the pinch-off point and isolates the semiconductor layer 108 from an external side.

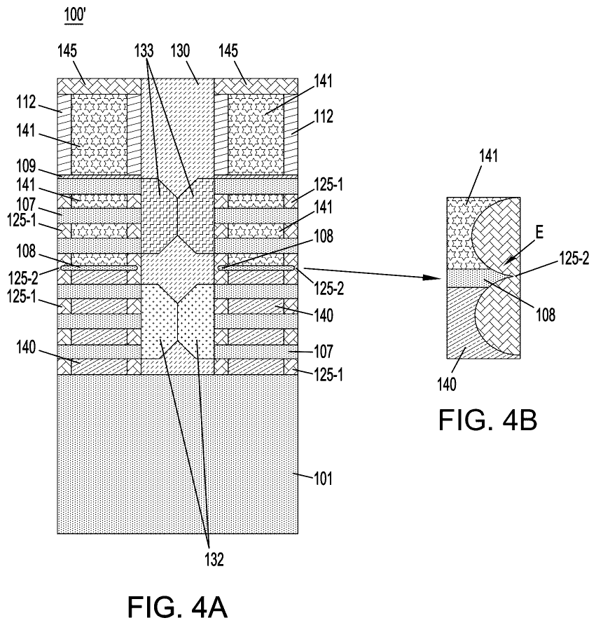

Referring to FIGS. 4A and 4B, although not shown in the previous figures, multiple stacked structures including the sacrificial layers 105, channel layers 107, dummy gate portion 111, gate spacers 112 and hardmask layer 120 are formed on the semiconductor substrate 101. For example, the semiconductor structure 100′ illustrates two stacked structures, but more than two stacked structures can be formed on the semiconductor substrate 101. As can be understood from FIG. 4A, first and second source/drain regions 132 and 133 are grown from the sides of the channel layers 107. The first type inner spacers 125-1 and second type inner spacers 125-2 cover the sacrificial layers 105 and the semiconductor layer 108 during the epitaxial growth of the first and second source/drain regions 132 and 133 and lateral epitaxial growth does not occur from the sacrificial layers 105 or the semiconductor layer 108.

Side surfaces of respective ones of the channel layers 107 contact a side surface at least one adjacent first source/drain region 132 or second source/drain region 133. The semiconductor layer 108 is electrically isolated from and does not contact the first and second source/drain regions 132 and 133.

According to a non-limiting embodiment of the present invention, the conditions of the epitaxial growth process for the first and second source/drain regions 132 and 133 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr—about 300 Torr. In the case of n-type FETS (nFETs), the first and second source/drain regions 132 and 133 can comprise silicon doped with n-type dopants including, for example, phosphorus (P), arsenic (As) and antimony (Sb). In the case of p-type FETS (pFETs), the first and second source/drain regions 132 and 133 can comprise silicon doped with p-type dopants including, for example, boron (B), boron fluoride (BF₂), gallium (Ga), indium (In), and thallium (TI).

An inter-layer dielectric (ILD) layer 130 is deposited to fill in portions on and around the first and second source/drain regions 132 and 133. The ILD layer 130 is deposited using deposition techniques such as, for example, CVD, PECVD, RFCVD, PVD, ALD, MBD, PLD, and/or LSMCD, followed by a planarization process, such as, CMP to remove excess portions of the ILD layer 130 deposited on top of the hardmask layers 120 and gate spacers 112, and to remove the hardmask layers 120 and portions of the gate spacers 112 to expose the dummy gate portions 111. The ILD layer 130 may comprise, for example, SiOx, SiOC, SiOCN or some other dielectric material.

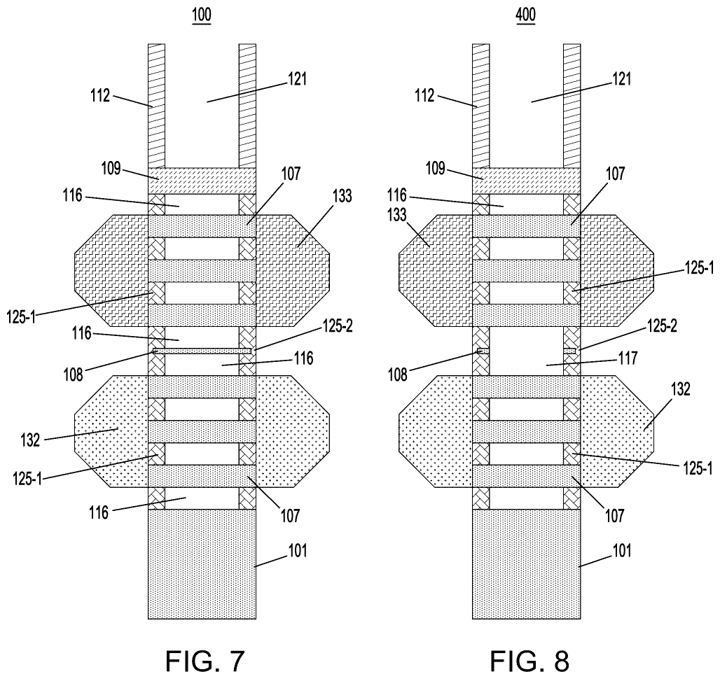

The dummy gate portions 111 are selectively removed to create vacant areas where gate structures will be formed in place of the dummy gate portions 111. The selective removal can be performed using, for example, hot ammonia to remove a-Si. In addition, the sacrificial layers 105 are selectively removed to create vacant areas where gate structures will be formed in place of the sacrificial layers 105. The sacrificial layers 105 are selectively removed with respect to the channel layers 107 and the semiconductor layer 108. The selective removal can be performed using, for example, a dry HCl etch. FIG. 7 illustrates an example where dummy gate portions 111 have been selectively removed to create vacant areas 121 and where sacrificial layers 105 have been selectively removed with respect to the channel layers 107 and the semiconductor layer 108 to create vacant areas 116. In FIG. 7, the semiconductor layer 108 remains. In an alternate semiconductor structure 400 in FIG. 8, a central portion of the semiconductor layer 108 not covered by the second type inner spacers 125-2 is also removed to create a single vacant area 117. In the alternate semiconductor structure 400 of FIG. 8, the central portion of the semiconductor layer 108 may be consumed/eroded during removal of the sacrificial layers 105. In other respects, the alternate semiconductor structure 400 is the same as the semiconductor structure 100 of FIG. 7.

Referring back to FIGS. 4A and 4B, following removal of the dummy gate portions 111 and sacrificial layers 105, the channel layers 107 are suspended, and first and second gate structures 140 and 141, including, for example, gate and dielectric portions are formed in the vacant area (e.g., vacant areas 116 and 121) left by removal of the dummy gate portions 111 and the sacrificial layers 105. In illustrative embodiments, the first gate structures 140 and first source/drain region 132 correspond to one or more first transistor devices, and the second gate structures 141 and second source/drain region 133 correspond to one or more second transistor devices. In some embodiments, the first and second transistor devices may have different doping types from each other (e.g., one may be an n-type FET, while the other is a p-type FET). Alternatively, the first and second transistor devices may have the same doping type. The area including the semiconductor layer 108 disposed between first and second gate structures 140 and 141 is an inter-device region. As can be seen, the semiconductor layer 108 is covered by the second type inner spacers 125-2 and is electrically isolated from and does not contact the first and second source/drain regions 132 and 133.

Alternatively, in the alternate semiconductor structure 400 in FIG. 8, following RMG processing, the single vacant area 117 created by the removal of the central portion of the semiconductor layer 108 is filled with a continuous gate structure that extends in a continuous configuration between an uppermost channel layer 107 of a first (bottom) transistor device and a lowermost channel layer 107 of a second (top) transistor device. The remaining portions of the semiconductor layer 108 in the alternate semiconductor structure 400 of FIG. 8 are covered by the second type inner spacers 125-2 and are electrically isolated from and do not contact the first and second source/drain regions 132 and 133.

Each of the first and second gate structures 140 and 141 includes a gate dielectric layer such as, for example, a high-K dielectric layer including, but not necessarily limited to, HfO₂(hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the first and second gate structures 140 and 141 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired. In some embodiments, the materials of the first and second gate structures 140 and 141 may differ from each other.

In addition to the first and second gate structures 140 and 141, self-aligned contact (SAC) cap layers 145 are formed in place of upper parts of the dummy gate portions 111. The SAC cap layers 145 include, but are not necessarily limited to, silicon SiN, SiBN, SiBCN or SiOCN. According to an embodiment of the present invention, the SAC cap layers 145 are deposited on top surfaces of the second gate structures 141 using, for example, deposition techniques including, but not limited to, CVD, PECVD, RFCVD, PVD, ALD, MLD, MBD, PLD, LSMCD, sputtering, and/or plating, followed by a planarization process, such as, for example, CMP. The SAC cap layers 145 function as placeholders for subsequently formed gate contacts.

As shown in FIG. 4B, the second type inner spacers 125-2 may have a rounded shape on internal sides thereof. The second type inner spacers 125-2 on left and right sides respectively form a continuous structure from a second (top) gate structure 141 to a first (bottom) gate structure 140 around an end portion E of the semiconductor layer 108 such that each second type inner spacer 125-2 covers an end portion E and isolates the semiconductor layer 108 from an external side of the transistor structure where the ILD layer 130 and first and second source/drain regions 132 and 133 are formed. As can be seen, the end portion E connects upper and lower surfaces of the semiconductor layer 108. Part of each second type inner spacer 125-2 is formed over the upper surface of the semiconductor layer 108. Part of each second type inner spacer 125-2 is also formed under the lower surface of the semiconductor layer 108. Each second type inner spacer 125-2 includes respective parts formed on a side of the second (top) gate structure 141 and the first (bottom) gate structure 140, respectively.

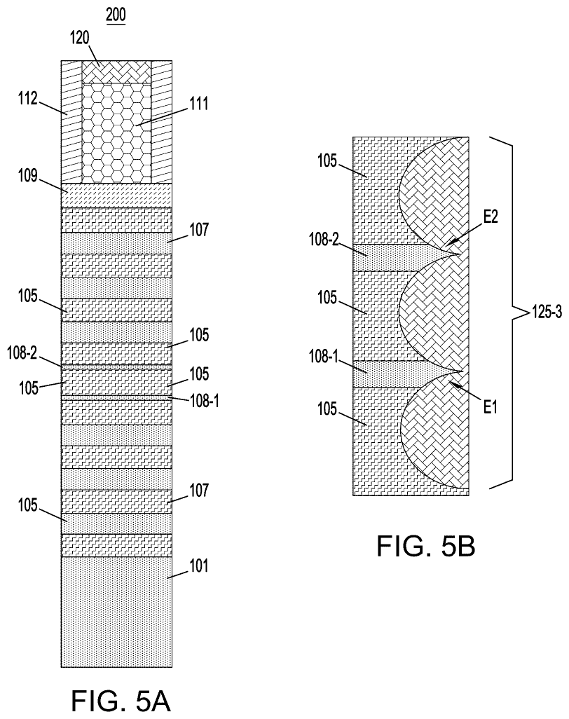

Referring to FIGS. 5A and 5B, in an alternative semiconductor structure 200, an inter-device region includes first and second semiconductor layers 108-1 and 108-2 disposed between adjacent pairs of sacrificial layers 105 (and between adjacent pairs of gate structures following RMG processing). In this case, each third type inner spacer 125-3 (e.g., on left and right sides) forms a continuous structure from a top sacrificial layer 105 to a middle sacrificial layer 105 and then to a bottom sacrificial layer 105 around end portions E1 and E2 of the first and second semiconductor layers 108-1 and 108-2 such that each third type inner spacer 125-3 covers end portions E1 and E2 and isolates the first and second semiconductor layers 108-1 and 108-2 from an external side.

As can be understood, following RMG processing where the sacrificial layers are replaced with gate structures, the third type inner spacers 125-3 on left and right sides respectively form a continuous structure from a top gate structure to a middle gate structure and then to a bottom gate structure around end portions E1 and E2 of the first and second semiconductor layers 108-1 and 108-2 such that each third type inner spacer 125-3 covers end portions E1 and E2 and isolates the first and second semiconductor layers 108-1 and 108-2 from an external side of a transistor structure where an ILD layer and source/drain regions are formed. In the alternative semiconductor structure 200, two semiconductor layers (e.g., first and second semiconductor layers 108-1 and 108-2) are shown between respective pairs of sacrificial layers 105. However, the embodiments are not necessarily limited thereto, and more than two semiconductor layers between respective pairs of sacrificial layers 105 (and eventually gate structures) can be formed in an inter-device region to increase a separation distance between the top and bottom devices.

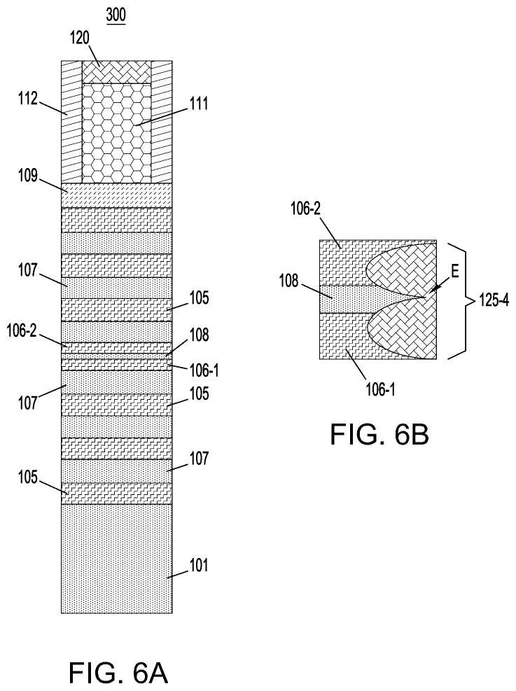

Referring to FIGS. 6A and 6B, in another alternative semiconductor structure 300, to reduce a separation distance between the top and bottom devices, an inter-device region includes semiconductor layer 108 disposed between first and second sacrificial semiconductor layers 106-1 and 106-2. The first and second sacrificial semiconductor layers 106-1 and 106-2 are thinner (have reduced height) than the sacrificial layers 105, but otherwise have the same or similar materials as the sacrificial layers 105. Following RMG processing, the resulting gate structures between which the semiconductor layer 108 is disposed are thinner than the remaining gate structures of a top nanosheet transistor and a bottom nanosheet transistor device. In this case, each fourth type inner spacer 125-4 (e.g., on left and right sides) is similar to the second type inner spacers 125-2, but has a flatter profile (decreased thickness) due to the decreased thicknesses of the first and second sacrificial semiconductor layers 106-1 and 106-2 and subsequently formed corresponding gate structures.

As can be understood, following RMG processing where the first and second sacrificial semiconductor layers 106-1 and 106-2 are replaced with gate structures, the fourth type inner spacers 125-4 on left and right sides respectively form a continuous structure from a top gate structure to a bottom gate structure around end portion E of semiconductor layer 108 such that each fourth type inner spacer 125-4 covers an end portion E and isolates the semiconductor layer 108 from an external side of a transistor structure where an ILD layer and source/drain regions are formed.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming protective dielectric spacers for nanosheet transistors in an inter-device region to prevent parasitic epitaxy growth. With conventional approaches, parasitic source/drain epitaxial layers grow in a separation region between bottom and top devices in a stacked transistor structure. Current techniques result in the generation of a parasitic channel when connected to a source/drain contact, and/or uncontrolled merging of bottom and top source/drain regions. Advantageously, the illustrative embodiments provide techniques for the formation of a thin semiconductor layer in an inter-device region so that a portion of the thin semiconductor layer can be removed during sacrificial layer removal. As a result, inner-spacers can be merged and form continuous isolating structures that prevent growth of parasitic source/drain epitaxial layers.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first nanosheet transistor structure;
a second nanosheet transistor structure stacked on the first nanosheet transistor structure;
a semiconductor layer disposed between the first nanosheet transistor structure and the second nanosheet transistor structure;
a first dielectric spacer disposed around a first end portion of the semiconductor layer; and
a second dielectric spacer disposed around a second end portion of the semiconductor layer, wherein the second end portion of the semiconductor layer is disposed opposite the first end portion.

2. The semiconductor device of claim 1, wherein the first end portion and the second end portion of the semiconductor layer respectively connect an upper surface of the semiconductor layer with a lower surface of the semiconductor layer.

3. The semiconductor device of claim 1, wherein:
a part of the first dielectric spacer is disposed over a first surface of the semiconductor layer and another part of the first dielectric spacer is disposed under a second surface of the semiconductor layer;
a part of the second dielectric spacer is disposed over the first surface of the semiconductor layer and another part of the second dielectric spacer is disposed under the second surface of the semiconductor layer.

4. The semiconductor device of claim 1, wherein a thickness of the semiconductor layer is in a range of about 1 nm to about 5 nm.

5. The semiconductor device of claim 4, wherein the thickness of the semiconductor layer is in a range of about 2 nm to about 3 nm.

6. The semiconductor device of claim 1, further comprising:
a first gate structure corresponding to the first nanosheet transistor structure formed on a first surface of the semiconductor layer; and
a second gate structure corresponding to the second nanosheet transistor structure formed on a second surface of the semiconductor layer;
wherein the second surface is opposite the first surface.

7. The semiconductor device of claim 6, wherein portions of the first dielectric spacer and of the second dielectric spacer are formed on sides of the first gate structure and of the second gate structure.

8. The semiconductor device of claim 1, wherein:
the first nanosheet transistor structure comprises a first plurality of gate structures alternately stacked with a first plurality of channel layers;
the second nanosheet transistor structure comprises a second plurality of gate structures alternately stacked with a second plurality of channel layers; and
the first and second dielectric spacers and the semiconductor layer are disposed between a first channel layer of the first plurality of channel layers and a second channel layer of the second plurality of channel layers.

9. The semiconductor device of claim 8, wherein a thickness of the semiconductor layer is less than thicknesses of respective ones of the first plurality of channel layers and of the second plurality of channel layers.

10. The semiconductor device of claim 1, further comprising at least one source/drain region disposed on a side of at least one of the first nanosheet transistor structure and the second nanosheet transistor structure, wherein the semiconductor layer is electrically isolated from the at least one source/drain region.

11. The semiconductor device of claim 1, wherein at least a portion of the first dielectric spacer and of the second dielectric spacer comprises a rounded shape.

12. A semiconductor device comprising:
a plurality of gate structures alternately stacked with a plurality of channel layers, wherein the plurality of channel layers contact at least one source/drain region disposed on at least one side of the plurality of gate structures and the plurality of channel layers;
a semiconductor layer disposed between a first gate structure and a second gate structure of the plurality of gate structures; and
at least one dielectric spacer disposed around at least one end portion of the semiconductor layer;
wherein the semiconductor layer is electrically isolated from the at least one source/drain region.

13. The semiconductor device of claim 12, wherein the at least one end portion of the semiconductor layer connects an upper surface of the semiconductor layer with a lower surface of the semiconductor layer.

14. The semiconductor device of claim 13, wherein the at least one dielectric spacer is disposed over a portion of the upper surface of the semiconductor layer and under a portion of the lower surface of the semiconductor layer.

15. The semiconductor device of claim 12, wherein portions of the at least one dielectric spacer are formed on sides of the first gate structure and of the second gate structure.

16. The semiconductor device of claim 12, wherein a thickness of the semiconductor layer is less than thicknesses of respective ones of the plurality of channel layers.

17. The semiconductor device of claim 12, wherein a thickness of the first gate structure and a thickness of the second gate structure are less than thicknesses of remaining ones of the plurality of gate structures.

18. A semiconductor device comprising:
a plurality of gate structures stacked with a plurality of channel layers, wherein the plurality of channel layers contact at least one source/drain region disposed on at least one side of the plurality of gate structures and the plurality of channel layers;
wherein two or more gate structures of the plurality of gate structures are disposed between two adjacent channel layers of the plurality of channel layers;
a dielectric spacer disposed on sides of each of the two or more gate structures, wherein the dielectric spacer comprises a continuous structure from a first one of the two or more gate structures to a last one of the two or more gate structures;
a semiconductor layer disposed between each pair of adjacent gate structures of the two or more gate structures;
wherein the dielectric spacer is disposed on sides of each semiconductor layer and each semiconductor layer is electrically isolated from the at least one source/drain region.

19. The semiconductor device of claim 18, wherein a thickness of each semiconductor layer is less than thicknesses of respective ones of the plurality of channel layers.

20. The semiconductor device of claim 18, wherein thicknesses of the two or more gate structures are less than thicknesses of remaining ones of the plurality of gate structures.
